(19) United States
(12) Patent Application Publication
(10) Pub. No.: US 2025/0212658 A1
(43) Pub. Date: Jun. 26, 2025

(54) ELECTROLUMINESCENT DISPLAY DEVICE

(71) Applicant: LG Display Co., Ltd., Seoul (KR)

(72) Inventor: Eunwoo Lee, Paju-si (KR)

(73) Assignee: LG Display Co., Ltd., Seoul (KR)

(21) Appl. No.: 18/986,151

(22) Filed: Dec. 18, 2024

(30) Foreign Application Priority Data
Dec. 22, 2023 (KR) 10-2023-0189783

(51) Int. Cl. H10K 59/80

(52) U.S. Cl. CPC H10K 59/873; H10K 59/8722

(57) ABSTRACT

An electroluminescent display device can include a substrate including a display area and a non-display area disposed outside the display area, an insulation layer disposed on the substrate, a light-emitting element disposed on the insulation layer, a bonding layer disposed on the light-emitting element, an encapsulation substrate disposed on the bonding layer, and a side seal covering side surfaces of the bonding layer and the encapsulation substrate, thereby blocking or delaying the introduction of moisture and improving reliability of a display panel of the display device.

### CROSS-REFERENCE TO RELATED APPLICATIONS

This application claims priority to Korean Patent Application No. 10-2023-0189783 filed on Dec. 22, 2023, in the Korean Intellectual Property Office, the entire disclosure of which is hereby expressly incorporated by reference into the present application.

### BACKGROUND

### Field

The present disclosure relates to an electroluminescent display device, and more particularly, to an electroluminescent display device having a narrow bezel.

### Discussion of the Related Art

Recently, display devices, which visually display electrical information signals, are being rapidly developed in accordance with the full-fledged entry into the information era. Various studies are being continuously conducted to develop a variety of display devices which are thin and lightweight, consume low power, and have improved performance.

As the representative display devices, there are a liquid crystal display device (LCD), an electrowetting display device (EWD), an organic light-emitting display device (OLED), and the like.

Among the display devices, an electroluminescent display device including the organic light-emitting display device refers to a display device that autonomously emits light. Unlike a liquid crystal display device, the electroluminescent display device does not require a separate light source and thus can be manufactured as a lightweight, thin display device. In addition, the electroluminescent display device is advantageous in terms of power consumption because the electroluminescent display device operates at a low voltage. Further, the electroluminescent display device is expected to be adopted in various fields since the electroluminescent display device is also excellent in implementation of colors, response speeds, viewing angles, and contrast ratios (CRs).

The electroluminescent display device is configured such that a light-emitting layer made of an organic material is disposed between two electrodes called an anode and a cathode. Further, when positive holes are injected into the light-emitting layer from the anode and electrons are injected into the light-emitting layer from the cathode, the injected electrons and positive holes are recombined and produce excitons in a light-emitting layer.

### SUMMARY OF THE DISCLOSURE

An object to be achieved by the present disclosure is to provide an electroluminescent display device capable of reducing a bezel width and blocking or delaying the introduction of moisture.

Objects of the present disclosure are not limited to the above-mentioned objects, and other objects, which are not mentioned above, can be clearly understood by those skilled in the art from the following descriptions.

In order to achieve the above-mentioned objects, one aspect of the present disclosure provides an electroluminescent display device a substrate which is divided into a display area and a non-display area disposed outside the display area, an insulation layer disposed on the substrate, a light-emitting element disposed on the insulation layer, a bonding layer disposed on the light-emitting element, an encapsulation substrate disposed on the bonding layer, and a side seal which cover side surfaces of the bonding layer and the encapsulation substrate.

Other detailed matters of the example embodiments of the present disclosure are included in the detailed description and the drawings.

According to aspects of the present disclosure, the side seal is added to the outer side of the display panel, and the additional bonding layer and the additional encapsulation substrate are formed on the side surface and the upper portion of the display panel, such that the introduction of moisture can be blocked or delayed, thereby improving the reliability of the display panel.

According to aspects of the present disclosure, the additional side seal can be formed at the upper outer side of the optical member to block a leak of light, thereby improving the image quality of the display panel.

The effects according to the present disclosure are not limited to the contents exemplified above, and more various effects are included in the present disclosure.

### BRIEF DESCRIPTION OF THE DRAWINGS

The above and other aspects, features and other advantages of the present disclosure will be more clearly understood from the following detailed description taken in conjunction with the accompanying drawings, in which:

FIG. 1 is a block diagram of an electroluminescent display device according to a first embodiment of the present disclosure;

FIG. 2 is a circuit diagram of a subpixel of the electroluminescent display device according to the first embodiment of the present disclosure;

FIG. 3 is a top plan view of the electroluminescent display device according to the first embodiment of the present disclosure;

FIG. 4 is a cross-sectional view of one subpixel according to some embodiments of the present disclosure;

FIG. 5 is a cross-sectional view taken along line I-I′ in FIG. 3;

FIG. 6 is a top plan view of an electroluminescent display device according to a second embodiment of the present disclosure;

FIG. 7 is a cross-sectional view taken along line II-II′ in FIG. 6;

FIG. 8 is a top plan view of an electroluminescent display device according to a third embodiment of the present disclosure;

FIG. 9 is a cross-sectional view taken along line III-III′ in FIG. 8;

FIGS. 10A to 10F are cross-sectional views exemplarily illustrating a process of manufacturing the electroluminescent display device in FIG. 9 according to the third embodiment of the present disclosure; and

FIG. 11 is a top plan view of an electroluminescent display device according to a fourth embodiment of the present disclosure.

### DETAILED DESCRIPTION OF THE EMBODIMENTS

Advantages and characteristics of embodiments of the present disclosure and a method of achieving the advantages and characteristics will be clear by referring to example embodiments described below in detail together with the accompanying drawings. However, the present disclosure is not limited to the example embodiments disclosed herein but will be implemented in various forms. The example embodiments are provided by way of example only so that those skilled in the art can fully understand the disclosures of the present disclosure and the scope of the present disclosure. Here, the term “can” fully encompasses all the meanings and coverages of the term “may.”

The shapes, sizes, ratios, angles, numbers, and the like illustrated in the accompanying drawings for describing the example embodiments of the present disclosure are merely examples, and the present disclosure is not limited thereto. Like reference numerals generally denote like elements throughout the disclosure. Further, in the following description of the present disclosure, a detailed explanation of known related technologies can be omitted to avoid unnecessarily obscuring the subject matter of the present disclosure. The terms such as “including,” “having,” and “comprising” used herein are generally intended to allow other components to be added unless the terms are used with the term “only”. Any references to singular can include plural unless expressly stated otherwise.

Components are interpreted to include an ordinary error range even if not expressly stated.

When the position relation between two parts is described using the terms such as “on”, “over”, “above”, “below”, and “next”, “under”, etc. one or more parts can be positioned between the two parts unless the terms are used with the term “immediately” or “directly”.

When an element or layer is disposed “on” another element or layer, it can be directly on the another element or layer, or another layer or another element (or additional layers/elements) can be interposed therebetween.

Although the terms “first”, “second”, and the like are used for describing various components, these components are not confined by these terms. These terms are merely used for distinguishing one component from the other components, and may not define order or sequence. Therefore, a first component to be mentioned below can be a second component in a technical concept of the present disclosure.

Same reference numerals generally denote same elements throughout the disclosure.

A size and a thickness of each component illustrated in the drawing are illustrated for convenience of description, and the present disclosure is not limited to the size and the thickness of the component illustrated.

The features of various embodiments of the present disclosure can be partially or entirely adhered to or combined with each other and can be interlocked and operated in technically various ways, and the embodiments can be carried out independently of or in association with each other.

Hereinafter, various embodiments of the present disclosure will be described in detail with reference to the drawings. All the components of each device/apparatus according to all embodiments of the present disclosure are operatively coupled and configured.

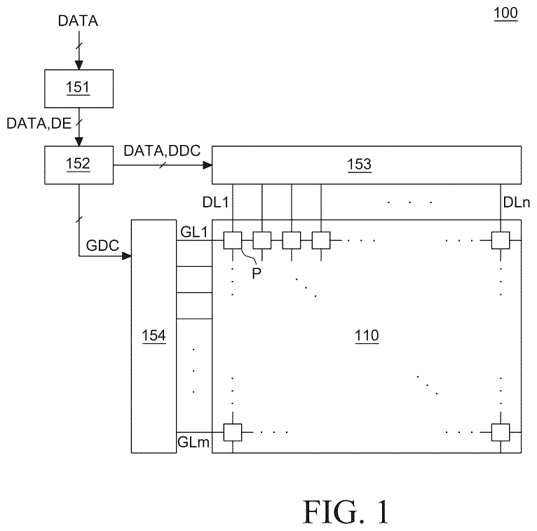

FIG. 1 is a block diagram of an electroluminescent display device according to a first embodiment of the present disclosure.

With reference to FIG. 1, an electroluminescent display device 100 according to the first embodiment of the present disclosure can include an image processor 151, a timing controller 152, a data driver 153, a gate driver 154, and a display panel 110.

The image processor 151 can output a data signal DATA, a data enable signal DE, and the like in response to the data signal DATA supplied from the outside.

The image processor 151 can output one or more of a vertical synchronizing signal, a horizontal synchronizing signal, and a clock signal in addition to the data enable signal DE.

The timing controller 152 receives the data signal DATA in addition to the data enable signal DE or the driving signals including the vertical synchronizing signal, the horizontal synchronizing signal, and the clock signal from the image processor 151. On the basis of the driving signal, the timing controller 152 can output a gate timing control signal GDC for controlling an operation timing of the gate driver 154 and output a data timing control signal DDC for controlling an operation timing of the data driver 153.

In addition, in response to the data timing control signal DDC supplied from the timing controller 152, the data driver 153 can sample and latch the data signal DATA supplied from the timing controller 152, convert the data signal DATA into a gamma reference voltage, and output the gamma reference voltage. The data driver 153 can output the gamma reference voltage as a data signal through data lines DL1 to DLn, where n is an integer greater than 1.

In addition, the gate driver 154 can output the gate signal while shifting a level of the gate voltage in response to the gate timing control signal GDC supplied from the timing controller 152. The gate driver 154 can output the gate signal through gate lines GL1 to GLm, where m is an integer greater than 1.

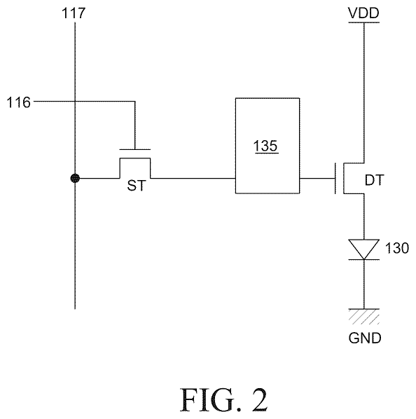

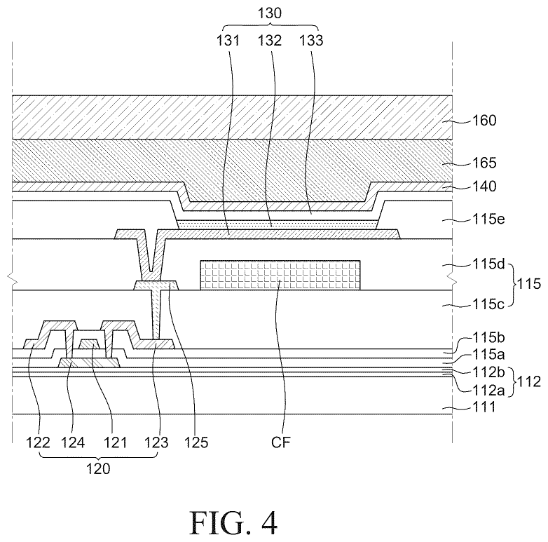

The display panel 110 can display an image as subpixels P emit light in response to a data signal and the gate signal supplied from the data driver 153 and the gate driver 154. A detailed structure of the subpixel P will be described with reference to FIGS. 2 and 4 according to an example of the present disclosure.

FIG. 2 is a circuit diagram of the subpixel of the electroluminescent display device according to the first embodiment of the present disclosure.

With reference to FIG. 2, the subpixel of the electroluminescent display device according to the first embodiment of the present disclosure can broadly include a switching transistor ST, a driving transistor DT, a compensating circuit 135, and a light-emitting element 130.

The light-emitting element 130 can operate to emit light based on a drive current produced by the driving transistor DT.

The switching transistor ST can perform a switching operation so that the data signal supplied through a data line 117 is stored, as a data voltage, in a capacitor in response to the gate signal supplied through a gate line 116.

In addition, the driving transistor DT can operate such that a predetermined drive current flows between a high-potential power line VDD and a low-potential power line GND while corresponding to data voltage stored in the capacitor.

The compensating circuit 135 is a circuit for compensating for a threshold voltage or the like of the driving transistor DT. The compensating circuit 135 can include one or more thin-film transistors and one or more capacitors. The compensating circuit 135 can have very various configurations depending on a compensation method.

An example is described in which the subpixel illustrated in FIG. 2 has a 2T(Transistor)1C(Capacitor) structure including the switching transistor ST, the driving transistor DT, the capacitor, and the light-emitting element 130. However, when the compensating circuit 135 is added, the subpixel can have various configurations such as 3T1C, 4T2C, 5T2C, 6T1C, 6T2C, 7T1C, 7T2C, or the like.

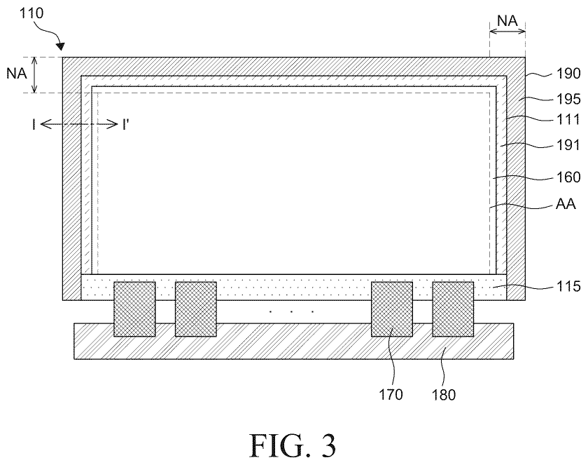

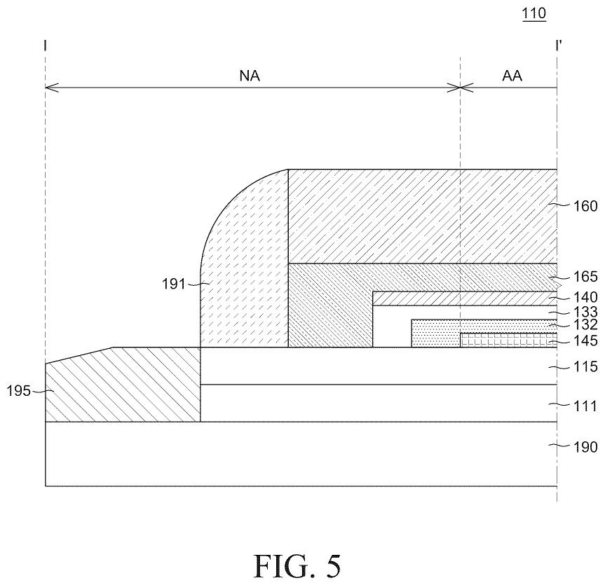

FIG. 3 is a top plan view of the electroluminescent display device according to the first embodiment of the present disclosure. FIG. 4 is a cross-sectional view of one subpixel according to an example of the present disclosure. FIG. 5 is a cross-sectional view taken along line I-I′ in FIG. 3.

Particularly, FIG. 5 illustrates a part of a cross-section of the display panel 110 of the first embodiment of the present disclosure including an optical member 190. For convenience of description, FIG. 5 schematically illustrates a pixel part 145 in a display area AA (or active area). The pixel part 145 can include various types of components including the light-emitting element 130.

With reference to FIG. 3, the electroluminescent display device 100 according to the first embodiment of the present disclosure can include the display panel 110, a flexible film 170, and a printed circuit board 180.

The display panel 110 is a panel configured to display images to a user.

The display panel 110 can include a display element configured to display images, a driving element configured to operate the display element, and lines configured to transmit various types of signals to the display element and the driving element. Different display elements can be defined depending on the types of display panels 110. For example, in a case in which the display panel 110 is an organic light-emitting display panel, the display element can be an organic light-emitting element including an anode, an organic light-emitting layer, and a cathode.

Hereinafter, the assumption is made that the display panel 110 is the organic light-emitting display panel. However, the display panel 110 is not limited to the organic light-emitting display panel.

The display panel 110 can include the display area AA and a non-display area NA (or non-active area). The non-display area NA can surround the display area AA entirely or only in part (s).

The display area AA is an area of the display panel 110 in which images are displayed.

The display area AA can include a plurality of subpixels configured to constitute a plurality of pixels, and a circuit configured to operate the plurality of subpixels. The plurality of subpixels is minimum units that constitute the display area AA. The display element can be disposed in each of the plurality of subpixels. The plurality of subpixels can constitute the pixel. For example, the plurality of subpixels can each include the light-emitting element including the anode, a light-emitting layer, and a cathode. However, the present disclosure is not limited thereto. In addition, the circuit configured to operate the plurality of subpixels can include driving elements, lines, and the like. For example, the circuit can include a thin-film transistor, a storage capacitor, a gate line, a data line, and the like. However, the present disclosure is not limited thereto.

The non-display area NA is an area in which no image is displayed.

FIG. 3 illustrates that the non-display area NA surrounds the display area AA having a quadrangular shape. However, the shapes and arrangements of the display area AA and the non-display area NA are not limited to the example illustrated in FIG. 3.

The display area AA and the non-display area NA can be suitable for the design of an electronic device equipped with the electroluminescent display device 100. For example, an example shape of the display area AA can be a pentagonal shape, a hexagonal shape, a circular shape, an elliptical shape, or the like.

Various lines and circuits for operating the organic light-emitting element in the display area AA can be disposed in the non-display area NA. For example, the non-display area NA can include link lines for transmitting signals to the plurality of subpixels and the circuit in the display area AA. The non-display area NA can include a drive integrated circuit (IC) such as a gate driver IC and a data driver IC. However, the present disclosure is not limited thereto.

Meanwhile, the left and right sides in FIG. 3 can be defined as gate pad parts on which the gate driver IC is disposed. The lower side in FIG. 3 can be defined as a data pad part connected to the flexible film. However, the present disclosure is not limited thereto.

The gate driver IC can be formed independently of the display panel 110 and electrically connected to the display panel 110 in various ways. However, the gate driver IC can be configured in a gate-in-panel (GIP) manner so as to be mounted in the display panel 110.

The electroluminescent display device 100 can include various additional elements configured to create various signals or operate the pixels in the display area AA. The additional elements for operating the pixel can include an inverter circuit, a multiplexer, an electrostatic discharge (ESD) circuit, and the like. The electroluminescent display device 100 can also include additional elements related to functions other than the function of operating the pixel. For example, the electroluminescent display device 100 can include additional elements that provide a touch detection function, a user certification function (e.g., fingerprint recognition), a multi-level pressure detection function, a tactile feedback function, and the like. The additional elements can be positioned in the non-display area NA and/or an external circuit connected to a connection interface.

In addition, the flexible film 170 can be a film configured to supply signals to the plurality of subpixels and the circuit in the display area AA. The flexible film 170 can be electrically connected to the display panel 110. The flexible film is disposed at one end of the non-display area NA of the display panel 110. The flexible film can supply power voltage, data voltage, and the like to the plurality of subpixels and the circuit in the display area AA. For example, the drive IC such as the data driver IC can be disposed on the flexible film 170.

The printed circuit board 180 can be disposed at one end of the flexible film 170 and connected to the flexible film 170. The printed circuit board 180 is a component for supplying a signal to the drive IC. The printed circuit board 180 can supply various signals, such as driving signals and data signals, to the drive IC.

Meanwhile, in order to ensure reliability of the inhibition of penetration of moisture, the electroluminescent display device 100 requires a minimum bezel distance. In addition, the non-display area NA of the electroluminescent display device 100, except for the display area AA for displaying images, needs to have a slim size to meet the requirement of the slim electroluminescent display device 100. However, in case that a bezel distance decreases, an effect of delaying the moisture penetration can deteriorate. In particular, in a bottom emission type display device, an adhesive layer, which is configured as a polymer adhesive film, and an encapsulation substrate 160, which is configured as a metal sheet, can be used to protect the light-emitting element from outside moisture, oxygen, or the like. For example, a pressure sensitive adhesive (PSA), in which calcium oxide (CaO) is dispersed in olefin resin, can be used as the adhesive layer. Because the effect of suppressing the moisture penetration significantly depends on the calcium oxide, the effect of delaying the moisture penetration can deteriorate in case that the bezel distance decreases. In addition, in case that the calcium oxide content is increased to suppress the moisture penetration, the bonding properties of the adhesive layer can be degraded, and the display area AA can be physically damaged by the dented calcium oxide.

Therefore, in the first embodiment of the present disclosure, a side seal 191 can be added to an outer side of the display panel 110 to delay the introduction of moisture, thereby improving the reliability of the display panel 110. In addition, an additional side seal 195 can be formed at an upper outer side of the optical member 190 to block a leak of light, thereby improving the image quality of the display panel 110.

The side seal 191 can be referred to as a first side seal, and the additional side seal 195 can be referred to as a second side seal.

For example, the side seal 191 and the additional side seal 195 of the first embodiment of the present disclosure can be disposed over the non-display area NA of three surfaces that surround a periphery of the display area AA, except for a lower end to which the flexible film 170 is attached. However, the present disclosure is not limited thereto.

For example, various types of insulation layers, which include a first planarization layer 115c and a second planarization layer 115d, can be disposed on a substrate 111 and disposed at the lower end of the display area AA at which the side seal 191 and the additional side seal 195 are not disposed.

Various components, which include the side seal 191 and the additional side seal 195 and constitute the electroluminescent display device 100 according to the first embodiment of the present disclosure, will be described in detail with reference to FIGS. 4 and 5.

With reference to FIGS. 4 and 5, the substrate 111 can be divided into the display area AA and the non-display area NA disposed outside the display area AA.

A thin-film transistor 120 and the light-emitting element 130 can be disposed in the display area AA of the substrate 111. The non-display area NA of the substrate 111 can include a GIP area. A GIP circuit part can be disposed in the GIP area of the substrate 111.

The substrate 111 serves to support and protect the components of the electroluminescent display device that are disposed above the substrate 111.

Recently, the flexible substrate 111 can be made of a flexible material such as plastic having flexibility.

The flexible substrate 111 can be provided in the form of a film made of one selected from a group consisting of polyester-based polymer, silicon-based polymer, acrylic polymer, polyolefin-based polymer, and a copolymer thereof.

A light-blocking layer can be disposed on the substrate 111.

The light-blocking layer can be made of a metallic material having a light-blocking function in order to inhibit outside light from entering a semiconductor layer 124.

For example, the light-blocking layer can be configured as a single-layer or multilayer structure made of any one of opaque metallic materials such as aluminum (Al), chromium (Cr), tungsten (W), titanium (Ti), nickel (Ni), neodymium (Nd), molybdenum (Mo), copper (Cu), and an alloy thereof.

A buffer layer 112 can be disposed on the substrate 111 on which the light-blocking layer is disposed.

For example, the buffer layer 112 is a functional layer for protecting various types of electrodes and lines from impurities, such as moisture, oxygen, or alkaline ions, introduced from the substrate 111 or a lower side. The buffer layer 112 can have a multilayer structure including a first buffer layer 112a and a second buffer layer 112b. However, the present disclosure is not limited thereto.

For example, the buffer layer 112 can be made of silicon oxide (SiOx) or silicon nitride (SiNx) or configured as a multilayer structure made of silicon oxide (SiOx) and silicon nitride (SiNx). However, the present disclosure is not limited thereto. The buffer layer 112 can be excluded depending on the types of thin-film transistors 120.

The buffer layer 112 can include a contact hole through which a part of the light-blocking layer is exposed.

The thin-film transistor 120 can be disposed above the buffer layer 112.

The thin-film transistor 120 in the display area AA can be a driving transistor. For convenience, FIG. 4 illustrates only the driving transistor 120. The electroluminescent display device can also include a switching transistor, a sensing transistor, a compensating circuit, and the like.

In this case, in response to a signal received from the switching transistor, the driving transistor 120 can transmit electric current, which is transmitted through the power line, to the anode 131. The driving transistor 120 can control light emission on the basis of the electric current transmitted to the anode 131.

To this end, the driving transistor 120 can include a gate electrode 121, the semiconductor layer 124, a source electrode 122, and a drain electrode 123.

The switching transistor is turned on by a gate pulse supplied through the gate line and transmits a data voltage, which is supplied through the data line, to the gate electrode 121 of the driving transistor 120.

The semiconductor layer 124 can be disposed on the second buffer layer 112b.

The semiconductor layer 124 can be made of polysilicon (p-Si). In this case, a predetermined area of the semiconductor layer 124 can be doped with impurities. In addition, the semiconductor layer 124 can be made of amorphous silicon (a-Si) or various organic semiconductor materials such as pentacene. Further, the semiconductor layer 124 can be made of an oxide semiconductor.

The oxide semiconductor is excellent in mobility and uniformity properties. The oxide semiconductor can be made of materials based on indium-tin-gallium-zinc oxide (InSnGaZnO) which is quaternary metal oxide, materials based on indium-gallium-zinc oxide (InGaZnO), indium-tin-zinc oxide (InSnZnO), indium-aluminum-zinc oxide (InAlZnO), tin-gallium-zinc oxide (SnGaZnO), aluminum-gallium-zinc oxide (AlGaZnO), and tin-aluminum-zinc oxide (SnAlZnO) which are ternary metal oxide, materials based on indium-zinc oxide (InZnO), tin-zinc oxide (SnZnO), aluminum-zinc oxide (AlZnO), zinc-magnesium oxide (ZnMgO), tin-magnesium oxide (SnMgO)), indium-magnesium oxide (InMgO), and indium-gallium oxide (InGaO) which are binary metal oxide, and materials based on indium oxide (InO), tin oxide (SnO), and zinc oxide (ZnO). The present disclosure is not limited to a composition ratio of the respective elements.

The semiconductor layer 124 can include source and drain areas including p-type or n-type impurities and a channel area between the source area and the drain area. The semiconductor layer 124 can further include a low-concentration doping area between the source and drain areas adjacent to the channel area. However, the present disclosure is not limited thereto.

The source and drain areas are areas in which impurities are doped at high concentration. The source electrode 122 and the drain electrode 123 of the thin-film transistor 120 can be respectively connected to the source and drain areas.

The p-type impurities or n-type impurities can be used as impurities ions. The p-type impurity can be one of boron (B), aluminum (Al), gallium (Ga), and indium (In). The n-type impurity can be one of phosphorus (P), arsenic (As), and antimony (Sb).

The channel area can be doped with the n-type or p-type impurities depending on the structures of the thin-film transistors of NMOS or PMOS.

A gate insulation layer 115a can be disposed on the semiconductor layer 124. For example, the gate insulation layer 115a can be made of an insulating inorganic material such as silicon oxide (SiOx) or silicon nitride (SiNx). In addition, the gate insulation layer 115a can be made of an insulating organic material or the like.

The gate electrode 121 can be disposed on the gate insulation layer 115a. The gate electrode 121 can be made of various electrically conductive materials, for example, magnesium (Mg), aluminum (Al), nickel (Ni), chromium (Cr), molybdenum (Mo), tungsten (W), gold (Au), or an alloy thereof.

An interlayer insulation layer 115b can be disposed on the gate electrode 121. For example, the interlayer insulation layer 115b can be made of silicon oxide (SiOx) or silicon nitride (SiNx) or configured as a multilayer structure made of silicon oxide (SiOx) and silicon nitride (SiNx).

The source electrode 122 and the drain electrode 123 can be disposed on the interlayer insulation layer 115b.

In this case, the source electrode 122 and the drain electrode 123 can each be configured as a single layer or multilayer made of a conductive metallic material such as aluminum (Al), molybdenum (Mo), chromium (Cr), gold (Au), titanium (Ti), nickel (Ni), neodymium (Nd), copper (Cu), or an alloy thereof. However, the present disclosure is not limited thereto.

An insulation layer 115 can be disposed above the thin-film transistor 120 configured as described above. The insulation layer 115 can be a planarization layer or an overcoat layer.

The insulation layer 115, which is a planarization layer, can have a multilayer structure including at least two layers. For example, the insulation layer 115 can include the first planarization layer 115c and the second planarization layer 115d. In this case, for example, the first planarization layer 115c can be disposed to cover the thin-film transistor 120 and disposed so that the source electrode 122 or the drain electrode 123 of the thin-film transistor 120 is partially exposed.

The insulation layer 115 can extend to the non-display area NA to cover the GIP area.

The insulation layer 115 can have a thickness of about 2 μm. However, the present disclosure is not limited thereto.

The structures of the thin-film transistor 120 can be classified into an inverted staggered structure and a coplanar structure depending on the positions of the constituent elements that constitute the thin-film transistor 120. For example, in the case of the thin-film transistor having the inverted staggered structure, the gate electrode can be positioned at a side opposite to the source electrode and the drain electrode based on the semiconductor layer. As illustrated in FIG. 4, in the case of the thin-film transistor 120 having the coplanar structure, the gate electrode 121 can be positioned at the same side as the source electrode 122 and the drain electrode 123 based on the semiconductor layer 124.

FIG. 4 illustrates the thin-film transistor 120 having the coplanar structure. However, the present disclosure is not limited thereto. The electroluminescent display device of the present disclosure can also include the thin-film transistor having the inverted staggered structure. In addition, some of the thin-film transistors 120 can have the coplanar structure, and some of the remaining thin-film transistors 120 can have the inverted staggered structure.

A connection electrode 125 can be disposed on the first planarization layer 115c and electrically connected to the thin-film transistor 120 and the light-emitting element 130. In addition, various metal layers can be disposed on the first planarization layer 115c and serve as electrodes and electric wires such as data lines or signal lines.

In addition, a color filter CF can be disposed on the first planarization layer 115c. However, the present disclosure is not limited thereto. The color filter CF can be excluded depending on the types of light-emitting elements 130.

The color filter CF of each of the subpixels can have any one of red, green, and blue colors. In addition, in the case of the subpixel that implements a white color, the color filter CF may not be disposed. The red, green, and blue colors can be variously arranged, and a black matrix capable of absorbing external light can be provided between the color filters CF.

In the case of the bottom emission type display device, the color filter CF can be positioned below the anode 131.

In addition, the second planarization layer 115d can be disposed on the first planarization layer 115c and the connection electrode 125. In the display device according to the first embodiment of the present disclosure, the configuration in which the insulation layer 115 is provided as two layers is based on the fact that the number of various types of signal lines increases as the display panel 110 has high resolution. The additional layer is provided because it is difficult to dispose all the lines on a single layer while ensuring minimum intervals. The addition of the additional layer (the second planarization layer 115d) can provide a margin for disposing lines, which further facilitates the disposition design of lines/electrodes. Further, in case that a dielectric material is used for the insulation layer 115 having a multilayer, the insulation layer 115 can serve to create capacitance between metal layers.

The second planarization layer 115d can be formed such that a part of the connection electrode 125 is exposed. The drain electrode 123 of the thin-film transistor 120 and the anode 131 of the light-emitting element 130 can be electrically connected by the connection electrode 125.

The light-emitting element 130 including the anode 131, an organic layer 132, and a cathode 133 can be disposed above the second planarization layer 115d.

The anode 131 can be disposed on the second planarization layer 115d.

The anode 131 is an electrode that serves to supply positive holes to the organic layer 132. The anode 131 can be connected to the thin-film transistor 120 through a contact hole formed in the insulation layer 115.

The electroluminescent display device can be implemented as a top emission type or a bottom emission type. In the case of the top emission type, a reflective layer made of an opaque conductive material with high reflectance, for example, silver (Ag), aluminum (Al), gold (Au), molybdenum (Mo), tungsten (W), chromium (Cr), or an alloy thereof can be additionally disposed on a lower portion of the anode 131 so that light, which is emitted from the organic layer 132, is reflected by the anode 131 and propagates upward, i.e., in a direction toward the cathode 133 at the upper side. In contrast, in the case of the bottom emission type, the anode 131 can be made of only a transparent electrically conductive material such as indium tin oxide (ITO), indium zinc oxide (IZO), or indium gallium zinc oxide (IGZO). Hereinafter, the description will be made on the assumption that the display panel 110 of the present disclosure is the bottom emission type.

A bank 115e can be disposed on the anode 131 and the second planarization layer 115d.

The bank 115e disposed above the anode 131 and the second planarization layer 115d can define the subpixel by dividing an area in which light is actually emitted, i.e., a light-emitting area.

For example, the bank 115e can be formed by performing photolithography after forming a photoresist on an upper portion of the anode 131.

A fine metal mask (FMM), which is a deposition mask, can be used to form the organic layer 132 of the light-emitting element 130.

In addition, a spacer can be disposed above the bank 115e and made of one of polyimide, photo acrylic, and benzocyclobutene which are transparent organic materials. The spacer is used to inhibit damage caused by contact with the deposition mask disposed on the bank 115e. The spacer serves to maintain a predetermined distance between the bank 115e and the deposition mask.

In this case, a part of the anode 131 can be exposed by removing the bank 115e in the light-emitting area.

The bank 115e can be disposed to extend to a part of the non-display area NA. However, the present disclosure is not limited thereto.

The organic layer 132 can be disposed between the anode 131 and the cathode 133.

The organic layer 132 serves to emit light. The organic layer 132 can include at least one of a hole injection layer (HIL), a hole transport layer (HTL), a light-emitting layer, an electron transport layer (ETL), and an electron injection layer (EIL). Some components can be excluded depending on the structure or properties of the electroluminescent display device. In this case, an electroluminescent layer and an inorganic light-emitting layer can be applied as the light-emitting layer.

The hole injection layer is disposed on the anode 131 and serves to facilitate the injection of the positive holes.

The hole transport layer is disposed on the hole injection layer and serves to smoothly transmit the positive holes to the light-emitting layer.

The light-emitting layer is disposed on the hole transport layer. The light-emitting layer can be made of a material capable of emitting light with a particular color, thereby emitting the light with the particular color. Further, a phosphorescent material or a fluorescent material can be used as the light-emitting material.

The electron injection layer can further be disposed on the electron transport layer. The electron injection layer is an organic layer that facilitates the injection of electrons from the cathode 133. The electron injection layer can be excluded depending on the structure and properties of the electroluminescent display device.

Meanwhile, an electron blocking layer for blocking a flow of electrons and/or a hole blocking layer for blocking a flow of positive holes is further disposed at a position adjacent to the light-emitting layer. Therefore, it is possible to inhibit the electron from moving from the light-emitting layer and passing through the adjacent hole transport layer when the electrons are injected into the light-emitting layer or inhibit the positive hole from moving from the light-emitting layer and passing through the adjacent electron transport layer when the positive holes are injected into the light-emitting layer, thereby improving luminous efficiency.

The organic layer 132 can be disposed to extend to a part of the non-display area NA. However, the present disclosure is not limited thereto.

The cathode 133 can be disposed on the organic layer 132.

The cathode 133 serves to supply electrons to the organic layer 132. The cathode 133 needs to supply electrons. Therefore, the cathode 133 can be made of a metallic material such as magnesium, a silver-magnesium alloy, or the like that is an electrically conductive material having a low work function. However, the present disclosure is not limited thereto.

The cathode 133 can extend to a part of the non-display area NA. For example, the cathode 133 can be disposed to extend to a part of the non-display area NA to cover an end of the organic layer 132. However, the present disclosure is not limited thereto.

A capping layer 140 can be disposed on the cathode 133.

The capping layer 140 can serve to assist in protecting the light-emitting element 130 and efficiently discharging light, which is generated by the organic layer 132, to the outside.

For example, the capping layer 140 can be made of a various organic compound having a refractive index of 1.7 or more to inhibit light, which propagates to the outside, from being totally reflected and lost. However, the present disclosure is not limited thereto.

The capping layer 140 can extend to a part of the non-display area NA. For example, the capping layer 140 can be disposed to extend to a part of the non-display area NA so as to be consistent with an end of the cathode 133. However, the present disclosure is not limited thereto.

A bonding layer 165 and the encapsulation substrate 160 can be disposed above the cathode 133.

The bonding layer 165 can be referred to as a first bonding layer, and the encapsulation substrate 160 can be referred to as a first encapsulation substrate.

For example, the bonding layer 165 can serve to delay side moisture penetration.

For example, the bonding layer 165 can further include a moisture absorbent such as a getter in addition to isobutyl rubber resin. The moisture absorbent can include calcium oxide.

The moisture absorbent can include particles having hygroscopicity. The moisture absorbent can absorb moisture, oxygen, and the like from the outside, thereby minimizing a degree to which moisture and oxygen penetrate into the display area AA.

For example, the bonding layer 165 can have a thickness of 40 to 60 um.

The encapsulation substrate 160 can be disposed on the bonding layer 165.

The encapsulation substrate 160, together with the bonding layer 165, can protect the light-emitting element 130 from outside moisture, oxygen, impact, and the like.

For example, the encapsulation substrate 160 can serve to suppress front moisture penetration.

For example, the encapsulation substrate 160 can be made of stainless steel (steel use stainless (SUS)) or Invar. However, the present disclosure is not limited thereto. In this case, Invar is an alloy of nickel and iron and has a very low coefficient of thermal expansion, such that Invar is relatively stable against a change in temperature.

For example, the encapsulation substrate 160 can have a thickness of 70 to 80 um.

Meanwhile, in the first embodiment of the present disclosure, the side seal 191 is added to the outer side of the display panel 110, thereby delaying the introduction of moisture. Therefore, it is possible to improve the reliability of the display panel 110.

For example, the side seal 191 can serve to suppress (block) the penetration of moisture into the bonding layer 165.

For example, the side seal 191 can be made of an organic or inorganic material with a low water vapor transmittance rate (WVTR). For example, the outer side of the display panel 110 can be coated with an organic material by using a dispenser or coated with an inorganic material by using spray coating.

For example, the side seal 191 can be formed over the non-display area NA of the three surfaces that surround the periphery of the display area AA, except for the lower end to which the flexible film is attached.

For example, the side seal 191 can be formed to cover side surfaces of the bonding layer 165 and the encapsulation substrate 160.

The optical member 190 according to the first embodiment of the present disclosure can be disposed on a rear surface of the display panel 110 configured as described above, i.e., a rear surface of the substrate 111.

In this case, a transparent adhesive layer having bonding properties can be interposed between the substrate 111 and the optical member 190.

The optical member 190 serves to improve the visibility of the electroluminescent display device by suppressing the reflection of external light and minimize a loss of light discharged to the outside from the light-emitting element 130.

The optical member 190 can include a phase difference layer and a linear polarizing plate.

For example, the phase difference layer can be configured as a quarter wave plate (QWP) that generates phase retardation of λ/4.

For example, a protective layer can be provided on the linear polarizing plate.

In addition, for example, a surface treatment layer including an anti-reflection film (AR film) can be positioned on the protective layer. The anti-reflection film can be formed by wet coating (anti-reflection coating) or dry sputtering (anti-reflection sputtering).

In addition, the additional side seal 195 can be disposed on the upper outer side of the optical member 190. As a result, it is possible to improve the image quality of the display panel 110 by blocking a leak of light at the outer side of the display panel 110.

For example, the additional side seal 195 can be formed over the non-display area NA of the three surfaces that surround the periphery of the display area AA, except for the lower end to which the flexible film is attached.

In addition, for example, the additional side seal 195 can be formed to cover side surfaces of the substrate 111 and the insulation layer 115. However, the present disclosure is not limited thereto. The additional side seal 195 can extend to cover a part of the side seal 191.

For example, the additional side seal 195 can be made of acrylic resin. However, the present disclosure is not limited thereto.

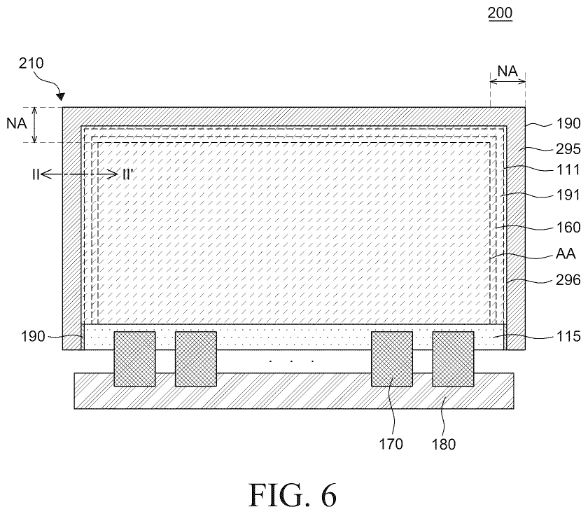

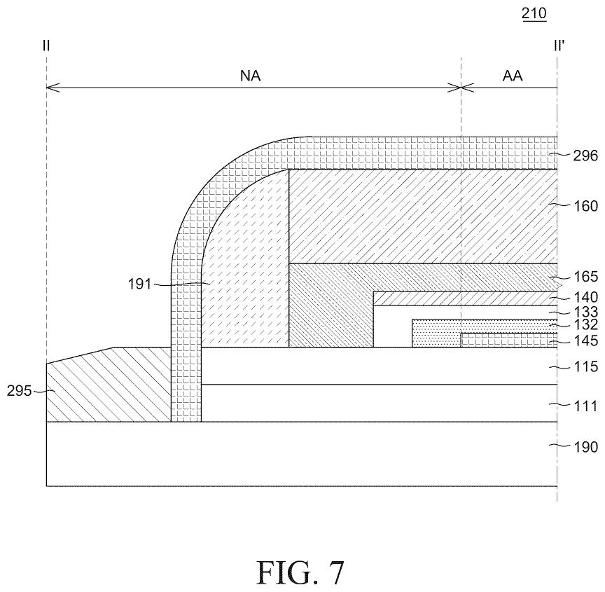

FIG. 6 is a top plan view of an electroluminescent display device according to a second embodiment of the present disclosure. FIG. 7 is a cross-sectional view taken along line II-II′ in FIG. 6.

An electroluminescent display device 200 of the second embodiment in FIGS. 6 and 7 is substantially identical in configuration to the above-mentioned electroluminescent display device of the first embodiment in FIGS. 3 to 5, except that an additional bonding layer 296 is added. Therefore, repeated descriptions of the identical components will be omitted or may be briefly provided. In addition, the same reference numerals are used for the same components. Hereinafter, the components denoted by the same reference numerals will be described with reference to FIGS. 1 to 5.

Particularly, FIG. 7 illustrates a part of a cross-section of a display panel 210 of the second embodiment of the present disclosure including the optical member 190.

With reference to FIGS. 6 and 7, in the electroluminescent display device 200 according to the second embodiment of the present disclosure, the thin-film transistor and the light-emitting element can be disposed in each of the subpixels and provided above the substrate 111.

The bonding layer 165 and the encapsulation substrate 160 can be disposed above the light-emitting element.

For example, the bonding layer 165 can serve to delay side moisture penetration.

For example, the bonding layer 165 can further include a moisture absorbent such as a getter in addition to isobutyl rubber resin. The moisture absorbent can include calcium oxide.

For example, the bonding layer 165 can have a thickness of 40 to 60 um.

The encapsulation substrate 160 can be disposed on the bonding layer 165.

The encapsulation substrate 160, together with the bonding layer 165, can protect the light-emitting element 130 from outside moisture, oxygen, impact, and the like.

For example, the encapsulation substrate 160 can serve to suppress front moisture penetration.

For example, the encapsulation substrate 160 can be made of stainless steel (steel use stainless (SUS)) or Invar. However, the present disclosure is not limited thereto.

For example, the encapsulation substrate 160 can have a thickness of 70 to 80 um.

Meanwhile, in the second embodiment of the present disclosure, the side seal 191 is added to the outer side of the display panel 210, thereby delaying the introduction of moisture. Therefore, it is possible to improve the reliability of the display panel 210.

For example, the side seal 191 can serve to suppress (block) the penetration of moisture into the bonding layer 165.

For example, the side seal 191 can be made of an organic or inorganic material with a low water vapor transmittance rate (WVTR).

For example, the side seal 191 can be formed over the non-display area NA of the three surfaces that surround the periphery of the display area AA, except for the lower end to which the flexible film 170 is attached.

For example, the side seal 191 can be formed to cover side surfaces of the bonding layer 165 and the encapsulation substrate 160.

In addition, the second embodiment of the present disclosure is characterized in that the additional bonding layer 296 is added to an outer side of the side seal 191 and a top surface of the encapsulation substrate 160 to delay the introduction of moisture into the side surface and change a moisture penetration route from a direction toward the side surface of the display panel 210 to a direction toward an upper side of the encapsulation substrate 160 along the additional bonding layer 296. Therefore, it is possible to further improve the reliability of the display panel 210.

The additional bonding layer 296 can be referred to as a second bonding layer.

For example, the additional bonding layer 296 can be disposed to cover side surfaces of the substrate 111 and the insulation layer 115, the outer side of the side seal 191, and the top surface of the encapsulation substrate 160.

For example, the additional bonding layer 296 can be formed over the non-display area NA of the three surfaces that surround the periphery of the display area AA, except for the lower end to which the flexible film 170 is attached.

For example, the additional bonding layer 296 can further include a moisture absorbent such as a getter in addition to isobutyl rubber resin. The moisture absorbent can include calcium oxide.

For example, the additional bonding layer 296 can have a thickness of 30 to 50 um.

The optical member 190 according to the second embodiment of the present disclosure can be disposed on a rear surface of the display panel 210 configured as described above, i.e., the rear surface of the substrate 111.

In addition, an additional side seal 295 can be disposed on the upper outer side of the optical member 190. As a result, it is possible to improve the image quality of the display panel 210 by blocking a leak of light at the outer side of the display panel 210.

For example, the additional side seal 295 can be formed over the non-display area NA of the three surfaces that surround the periphery of the display area AA, except for the lower end to which the flexible film 170 is attached.

For example, the additional side seal 295 can be formed to cover a part of a side surface of the additional bonding layer 296. However, the present disclosure is not limited thereto.

For example, the additional side seal 295 can be made of acrylic resin. However, the present disclosure is not limited thereto.

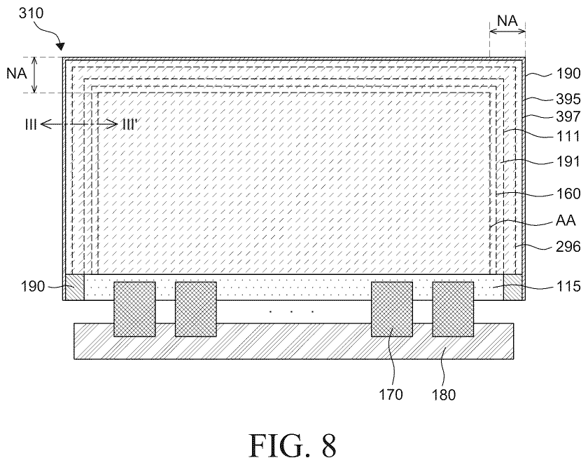

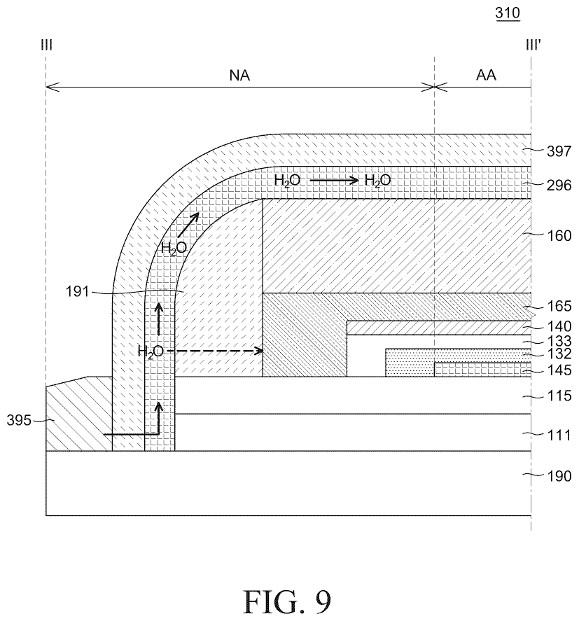

FIG. 8 is a top plan view of an electroluminescent display device according to a third embodiment of the present disclosure. FIG. 9 is a cross-sectional view taken along line III-III′ in FIG. 8.

An electroluminescent display device 300 of the third embodiment in FIGS. 8 and 9 is substantially identical in configuration to the above-mentioned electroluminescent display device of the first embodiment in FIGS. 3 to 5, except that the additional bonding layer 296 and an additional encapsulation substrate 397 are added. Therefore, repeated descriptions of the identical components will be omitted or may be briefly provided. In addition, the same reference numerals are used for the same components. Hereinafter, the components denoted by the same reference numerals will be described with reference to FIGS. 1 to 7.

Particularly, FIG. 9 illustrates a part of a cross-section of a display panel 310 according to the third embodiment of the present disclosure including the optical member 190.

With reference to FIGS. 8 and 9, in the electroluminescent display device 300 according to the third embodiment of the present disclosure, the thin-film transistor and the light-emitting element can be disposed in each of the subpixels and provided above the substrate 111.

The bonding layer 165 and the encapsulation substrate 160 can be disposed above the light-emitting element.

For example, the bonding layer 165 can serve to delay side moisture penetration.

For example, the bonding layer 165 can further include a moisture absorbent such as a getter in addition to isobutyl rubber resin. The moisture absorbent can include calcium oxide.

For example, the bonding layer 165 can have a thickness of 40 to 60 um.

The encapsulation substrate 160 can be disposed on the bonding layer 165.

The encapsulation substrate 160, together with the bonding layer 165, can protect the light-emitting element 130 from outside moisture, oxygen, impact, and the like.

For example, the encapsulation substrate 160 can serve to suppress front moisture penetration.

For example, the encapsulation substrate 160 can be made of stainless steel (steel use stainless (SUS)) or Invar. However, the present disclosure is not limited thereto.

For example, the encapsulation substrate 160 can have a thickness of 70 to 80 um.

In addition, in the third embodiment of the present disclosure, the side seal 191 is added to the outer side of the display panel 310, thereby delaying the introduction of moisture. Therefore, it is possible to improve the reliability of the display panel 310.

For example, the side seal 191 can serve to suppress (block) the penetration of moisture into the bonding layer 165.

For example, the side seal 191 can be made of an organic or inorganic material with a low water vapor transmittance rate (WVTR).

For example, the side seal 191 can be formed over the non-display area NA of the three surfaces that surround the periphery of the display area AA, except for the lower end to which the flexible film 170 is attached.

For example, the side seal 191 can be formed to cover side surfaces of the bonding layer 165 and the encapsulation substrate 160.

In addition, the third embodiment of the present disclosure is characterized in that the additional bonding layer 296 is added to an outer side of the side seal 191 and a top surface of the encapsulation substrate 160 to delay the introduction of moisture into the side surface and change a moisture penetration route from a direction toward the side surface of the display panel 310 to the direction toward the upper side of the encapsulation substrate 160 along the additional bonding layer 296. In particular, the third embodiment of the present disclosure is characterized in that the additional encapsulation substrate 397 is added to the outer side of the additional bonding layer 296, thereby suppressing the moisture penetration into the front surface of the display panel 310. Therefore, it is possible to further improve the reliability of the display panel 310. FIG. 9 illustrates the penetration of moisture and the moisture penetration route of the introduced moisture as an example. The additional bonding layer 296 and the additional encapsulation substrate 397 can guide the introduced moisture to the additional bonding layer 296 at the upper side and remarkably reduce the introduction of moisture into the bonding layer 165 at the lower side, thereby suppressing the occurrence of a defect caused by moisture.

The additional bonding layer 296 and the additional encapsulation substrate 397 of the third embodiment of the present disclosure are disposed on the display panel 310, i.e., side surfaces of the substrate 111 and the insulation layer 115, which can effectively block or delay the introduction of moisture into the pixel part 145 in the display area AA.

The additional encapsulation substrate 397 can be referred to as a second encapsulation substrate.

For example, the additional bonding layer 296 can be disposed to cover side surfaces of the substrate 111 and the insulation layer 115, the outer side of the side seal 191, and the top surface of the encapsulation substrate 160.

For example, the additional bonding layer 296 can be formed over the non-display area NA of the three surfaces that surround the periphery of the display area AA, except for the lower end to which the flexible film 170 is attached.

For example, the additional bonding layer 296 can further include a moisture absorbent such as a getter in addition to isobutyl rubber resin. The moisture absorbent can include calcium oxide.

For example, the additional bonding layer 296 can have a thickness of 30 to 50 um.

In addition, for example, the additional encapsulation substrate 397 can serve to suppress front moisture penetration.

For example, the additional encapsulation substrate 397 can be made of aluminum foil. However, the present disclosure is not limited thereto.

For example, the additional encapsulation substrate 397 can have a thickness of 10 to 30 um.

For example, the aluminum foil having a thickness of 10 to 30 μm and having high flexibility is used as the additional encapsulation substrate 397, such that the additional encapsulation substrate 397 is easily bent and deformed toward the side surface of the lower substrate 111.

The optical member 190 according to the third embodiment of the present disclosure can be disposed on a rear surface of the display panel 310 configured as described above, i.e., the rear surface of the substrate 111.

In addition, an additional side seal 395 can be disposed on the upper outer side of the optical member 190. As a result, it is possible to improve the image quality of the display panel 310 by blocking a leak of light at the outer side of the display panel 310.

For example, the additional side seal 395 can be formed over the non-display area NA of the three surfaces that surround the periphery of the display area AA, except for the lower end to which the flexible film 170 is attached.

In addition, for example, the additional side seal 395 can be formed to cover a part of a side surface of the additional encapsulation substrate 397. However, the present disclosure is not limited thereto.

For example, the additional side seal 395 can be made of acrylic resin. However, the present disclosure is not limited thereto.

For example, the additional side seal 395 can have a thickness of 80 to 140 um after laser cutting. However, the present disclosure is not limited thereto.

As described above, a width of the additional side seal 395 can be reduced by laser cutting, such that a final bezel size can be constantly maintained even though the additional bonding layer 296 and the additional encapsulation substrate 397 are added.

Hereinafter, a process of manufacturing the electroluminescent display device according to the third embodiment of the present disclosure will be described in detail with reference to the drawings.

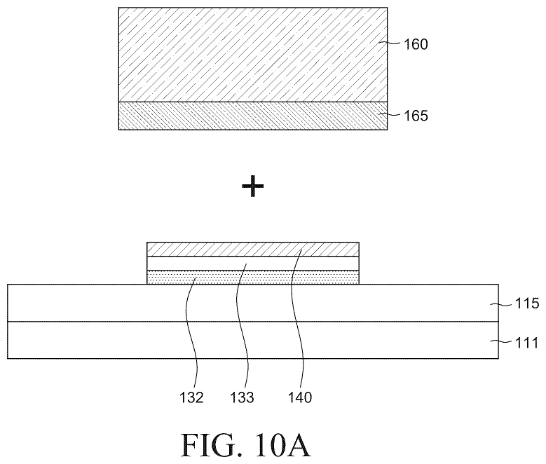

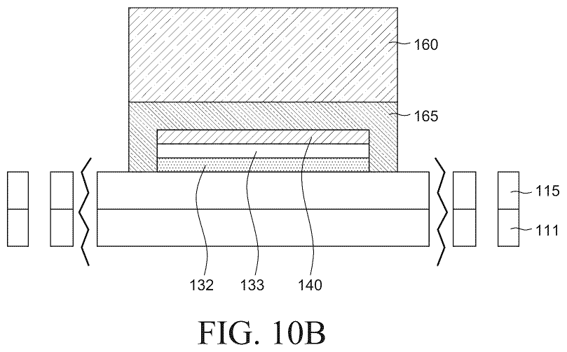

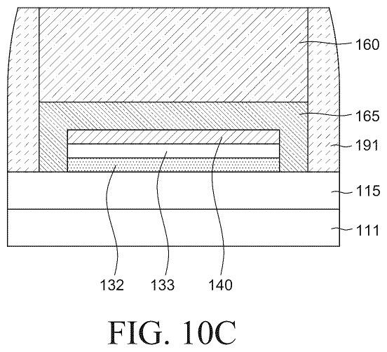

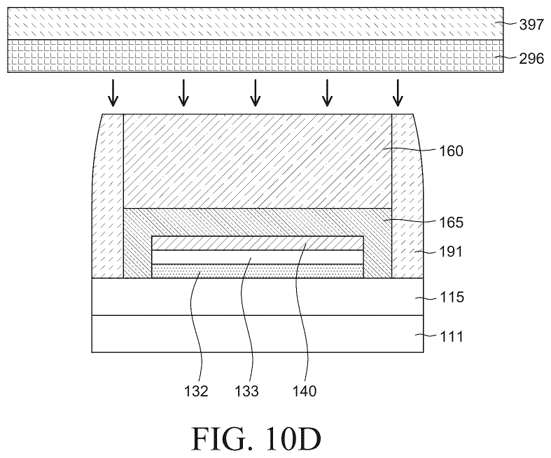

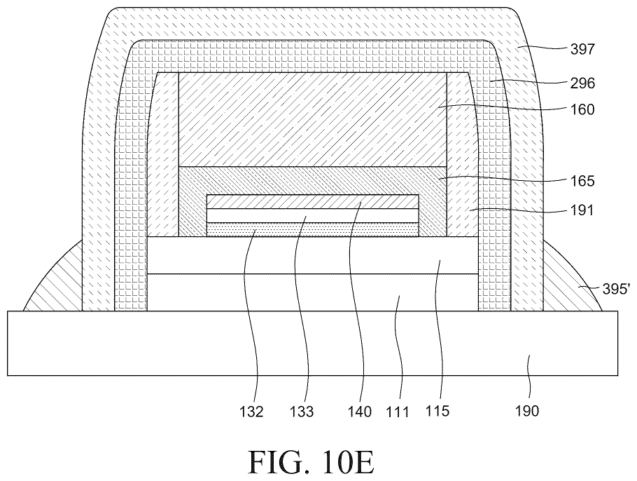

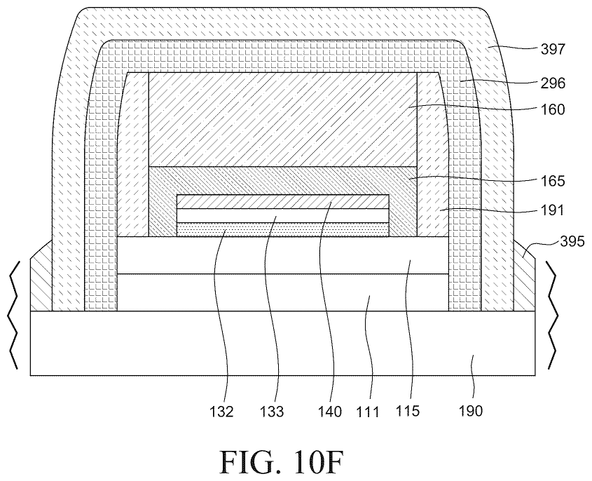

FIGS. 10A to 10F are cross-sectional views exemplarily illustrating a process of manufacturing the electroluminescent display device in FIG. 9 according to the third embodiment of the present disclosure.

With reference to FIG. 10A, the insulation layer 115 can be formed above the substrate 111 having the thin-film transistor formed for each of the subpixels.

The insulation layer 115 can have a multilayer structure including at least two layers. For example, the insulation layer 115 can include the first planarization layer and the second planarization layer.

Thereafter, the anode can be formed above the insulation layer 115 for each of the subpixels, and then the organic layer 132 can be formed above the anode.

Thereafter, the cathode 133 and the capping layer 140 can be formed on the organic layer 132.

The light-emitting element including the anode, the organic layer 132, and the cathode 133 can be formed above the insulation layer 115.

The organic layer 132 serves to emit light. The organic layer 132 can include at least one of a hole injection layer (HIL), a hole transport layer (HTL), a light-emitting layer, an electron transport layer (ETL), and an electron injection layer (EIL). Some components can be excluded depending on the structure or properties of the electroluminescent display device. In this case, an electroluminescent layer and an inorganic light-emitting layer can be applied as the light-emitting layer.

The organic layer 132 can be disposed to extend to a part of the non-display area. However, the present disclosure is not limited thereto.

The cathode 133 can be formed on the organic layer 132. The cathode 133 can extend to a part of the non-display area. For example, the cathode 133 can be disposed to extend to a part of the non-display area to cover the end of the organic layer 132. However, the present disclosure is not limited thereto.

The capping layer 140 can be formed on the cathode 133. The capping layer 140 can extend to a part of the non-display area. For example, the capping layer 140 can be disposed to extend to a part of the non-display area so as to be consistent with the end of the cathode 133. However, the present disclosure is not limited thereto.

With reference to FIGS. 10A and 10B, the bonding layer 165 and the encapsulation substrate 160 can be attached to the upper portion of the substrate 111 on which the capping layer 140 is formed.

For example, the bonding layer 165 can further include a moisture absorbent such as a getter in addition to isobutyl rubber resin. The moisture absorbent can include calcium oxide.

For example, the bonding layer 165 can have a thickness of 40 to 60 um.

The encapsulation substrate 160 can be disposed on the bonding layer 165.

For example, the encapsulation substrate 160 can be made of stainless steel (steel use stainless (SUS)) or Invar. However, the present disclosure is not limited thereto.

For example, the encapsulation substrate 160 can have a thickness of 70 to 80 um.

Thereafter, an edge of the substrate 111 and an edge of the insulation layer 115 can be ground.

After the grinding, the substrate 111 and the insulation layer 115 can further protrude outward than an end of the bonding layer 165 and an end of the encapsulation substrate 160.

Thereafter, with reference to FIG. 10C, the side seal 191 can be formed at the outer side of the display panel 110. For example, the top surface of the insulation layer 115, the side surface of the bonding layer 165, and the side surface of the encapsulation substrate 160, which protrude outward, can be coated with an organic or inorganic material with a low water vapor transmittance rate (WVTR). For example, the outer side of the display panel can be coated with an organic material by using a dispenser or coated with an inorganic material by using spray coating.

For example, the side seal 191 can be formed over the non-display area of the three surfaces that surround the periphery of the display area, except for the lower end to which the flexible film is attached.

For example, the side seal 191 can be formed to cover side surfaces of the bonding layer 165 and the encapsulation substrate 160.

Next, with reference to FIG. 10D, the additional bonding layer 296 and the additional encapsulation substrate 397 can be attached to the upper portion of the encapsulation substrate 160.

For example, the additional bonding layer 296 can be attached to cover the substrate 111, the insulation layer 115, the outer side of the side seal 191, and the top surface of the encapsulation substrate 160.

For example, the additional bonding layer 296 can be attached over the non-display area of the three surfaces that surround the periphery of the display area, except for the lower end to which the flexible film is attached.

For example, the additional bonding layer 296 can further include a moisture absorbent such as a getter in addition to isobutyl rubber resin. The moisture absorbent can include calcium oxide.

For example, the additional bonding layer 296 can have a thickness of 30 to 50 um.

In addition, for example, the additional encapsulation substrate 397 can be made of aluminum foil. However, the present disclosure is not limited thereto.

For example, the additional encapsulation substrate 397 can have a thickness of 10 to 30 um.

Thereafter, with reference to FIG. 10E, the optical member 190 according to the third embodiment of the present disclosure can be attached to the rear surface of the display panel, i.e., the rear surface of the substrate 111.

In this case, the transparent adhesive layer having bonding properties can be interposed between the substrate 111 and the optical member 190.

Thereafter, the upper outer side of the optical member 190 can be coated with sealant 395′. For example, the sealant 395′ can be made of acrylic resin. However, the present disclosure is not limited thereto.

In addition, for example, the sealant 395′ can be applied to cover a part of the side surface of the additional encapsulation substrate 397. However, the present disclosure is not limited thereto.

Thereafter, with reference to FIG. 10F, the additional side seal 395 can be formed at the upper outer side of the optical member 190 by cutting an edge of the optical member 190 and an edge of the sealant 395′ by a laser.

For example, the additional side seal 395 can be formed over the non-display area of the three surfaces that surround the periphery of the display area, except for the lower end to which the flexible film is attached.

In addition, for example, the additional side seal 395 can be formed to cover a part of the side surface of the additional encapsulation substrate 397. However, the present disclosure is not limited thereto.

For example, the additional side seal 395 can have a thickness of 80 to 140 um after laser cutting. However, the present disclosure is not limited thereto.

Meanwhile, the additional bonding layer and the additional encapsulation substrate of the present disclosure can be disposed on the top surface of the display panel. This configuration will be described in detail with reference to a fourth embodiment below.

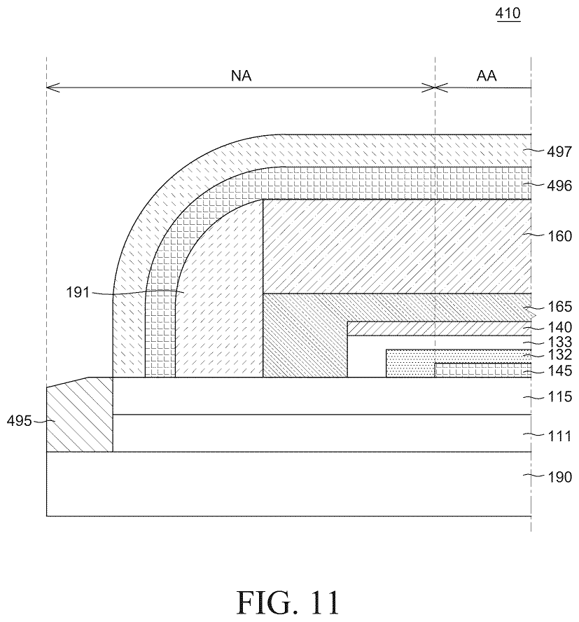

FIG. 11 is a top plan view of an electroluminescent display device according to a fourth embodiment of the present disclosure.

The electroluminescent display device of the fourth embodiment in FIG. 11 is substantially identical in configuration to the above-mentioned electroluminescent display device of the third embodiment in FIGS. 8 and 9, except that an additional bonding layer 496 and an additional encapsulation substrate 497 are disposed on a top surface of a display panel 410. Therefore, repeated descriptions of the identical components will be omitted or may be briefly provided. In addition, the same reference numerals are used for the same components. Hereinafter, the components denoted by the same reference numerals will be described with reference to FIGS. 1 to 9.

In addition, FIG. 11 illustrates a part of a cross-section of the display panel 410 of the fourth embodiment of the present disclosure including the optical member 190.

With reference to FIG. 11, in the electroluminescent display device according to the fourth embodiment of the present disclosure, the thin-film transistor and the light-emitting element can be disposed in each of the subpixels and provided above the substrate 111.

The bonding layer 165 and the encapsulation substrate 160 can be disposed above the light-emitting element.

In addition, the side seal 191 can be disposed at an outer side of the display panel 410.

In addition, in the fourth embodiment of the present disclosure, the additional bonding layer 496 can be disposed at the outer side of the side seal 191 and on the top surface of the encapsulation substrate 160. In addition, in the fourth embodiment of the present disclosure, the additional encapsulation substrate 497 can be disposed at the outer side of the additional bonding layer 496.

For example, the additional bonding layer 496 can be disposed on the top surface of the insulation layer 115 and cover the outer side of the side seal 191 and the top surface of the encapsulation substrate 160.

For example, the additional bonding layer 496 can be formed over the non-display area of the three surfaces that surround the periphery of the display area, except for the lower end to which the flexible film is attached.

For example, the additional bonding layer 496 can further include a moisture absorbent such as a getter in addition to isobutyl rubber resin. The moisture absorbent can include calcium oxide.

For example, the additional bonding layer 496 can have a thickness of 30 to 50 um.

In addition, for example, the additional encapsulation substrate 497 can be disposed on the top surface of the insulation layer 115 and cover the outer side of the additional bonding layer 496.

In addition, for example, the additional encapsulation substrate 497 can serve to suppress front moisture penetration.

For example, the additional encapsulation substrate 497 can be made of aluminum foil. However, the present disclosure is not limited thereto.

For example, the additional encapsulation substrate 497 can have a thickness of 10 to 30 um.

The optical member 190 according to the fourth embodiment of the present disclosure can be disposed on a rear surface of the display panel 410 configured as described above, i.e., the rear surface of the substrate 111.

In addition, an additional side seal 495 can be disposed on the upper outer side of the optical member 190.

For example, the additional side seal 495 can be formed over the non-display area of the three surfaces that surround the periphery of the display area, except for the lower end to which the flexible film is attached.

For example, the additional side seal 495 can be formed to cover side surfaces of the substrate 111 and the insulation layer 115. However, the present disclosure is not limited thereto. The additional side seal 495 can be formed to cover a part of the side surface of the additional encapsulation substrate 497.

For example, the additional side seal 495 can be made of acrylic resin. However, the present disclosure is not limited thereto.

For example, the additional side seal 495 can have a thickness of 80 to 140 um after laser cutting. However, the present disclosure is not limited thereto.

The example embodiments of the present disclosure can also be described as follows:

According to one or more embodiments of the present disclosure, an electroluminescent display device can be provided, which includes a substrate which is divided into a display area and a non-display area disposed outside the display area, an insulation layer disposed on the substrate, a light-emitting element disposed on the insulation layer, a bonding layer disposed on the light-emitting element, an encapsulation substrate disposed on the bonding layer, and a side seal which cover side surfaces of the bonding layer and the encapsulation substrate

According to one or more embodiments of the present disclosure, the electroluminescent display device can further comprise a flexible film which is disposed at one end of the non-display area, wherein the side seal can be disposed over the non-display area of three surfaces that surround a periphery of the display area, except for the end to which the flexible film is attached.

According to one or more embodiments of the present disclosure, the electroluminescent display device can further comprise an optical member disposed on a rear surface of the substrate, and an additional side seal which is disposed at an upper outer side of the optical member.

According to one or more embodiments of the present disclosure, the additional side seal can be disposed over the non-display area of three surfaces that surround a periphery of the display area, except for the end to which the flexible film is attached.

According to one or more embodiments of the present disclosure, the additional side seal can cover side surfaces of the substrate and the insulation layer.

According to one or more embodiments of the present disclosure, the additional side seal can extend to cover a part of the side seal.

According to one or more embodiments of the present disclosure, the electroluminescent display device can further comprise an additional bonding layer which is disposed at an outer side of the side seal and a top surface of the encapsulation substrate, so as to guide a moisture penetration route from a direction toward a side surface of the electroluminescent to a direction toward an upper side of the encapsulation substrate along the additional bonding layer.

According to one or more embodiments of the present disclosure, the additional bonding layer can cover side surfaces of the substrate and the insulation layer, the outer side of the side seal and the top surface of the encapsulation substrate.

According to one or more embodiments of the present disclosure, the electroluminescent display device can further comprise a flexible film which is disposed at one end of the non-display area, wherein the additional bonding layer is disposed over the non-display area of three surfaces that surround a periphery of the display area, except for the end to which the flexible film is attached.

According to one or more embodiments of the present disclosure, each of the boding layer and the additional bonding layer can include isobutyl rubber resin and a moisture absorbent.

According to one or more embodiments of the present disclosure, the additional side seal can cover a part of a side surface of the additional bonding layer.

According to one or more embodiments of the present disclosure, the additional side seal can include acrylic resin.

According to one or more embodiments of the present disclosure, the additional side seal can have a thickness of 80 to 140 um.

According to one or more embodiments of the present disclosure, the additional bonding layer can have a thickness of 30 to 50 um.

According to one or more embodiments of the present disclosure, the electroluminescent display device can further comprise an additional encapsulation substrate which is disposed at an outer side of the additional bonding layer.

According to one or more embodiments of the present disclosure, the additional encapsulation substrate has a thickness of 10 to 30 um.

According to one or more embodiments of the present disclosure, the additional encapsulation substrate can be made of aluminum foil.

According to one or more embodiments of the present disclosure, the additional side seal can cover a part of a side surface of the additional encapsulation substrate.

According to one or more embodiments of the present disclosure, the additional bonding layer can be disposed on a top surface of the insulation layer and cover the outer side of the side seal and the top surface of the encapsulation substrate.

According to one or more embodiments of the present disclosure, the additional encapsulation substrate can be disposed on a top surface of the insulation layer and cover an outer side of the additional bonding layer.

According to one or more embodiments of the present disclosure, the additional side seal can cover a part of a side surface of the additional encapsulation substrate.

According to one or more embodiments of the present disclosure, the side seal can be disposed on a top surface of the insulation layer, the side surface of the bonding layer, and the side surface of the encapsulation substrate.

According to one or more embodiments of the present disclosure, the electroluminescent display device can further comprise a connection electrode, wherein the insulation layer can include a first planarization layer and a second planarization layer, wherein the connection electrode can be disposed on the first planarization layer and electrically connected to the light-emitting element, and wherein the second planarization layer can be disposed on the first planarization layer and the connection electrode, and the second planarization layer can be formed such that a part of the connection electrode is exposed.

According to one or more embodiments of the present disclosure, the electroluminescent display device can further comprise a capping layer between the light-emitting element and the bonding layer, wherein the capping layer can be made of an organic compound having a refractive index of 1.7 or more.

According to one or more embodiments of the present disclosure, the capping layer can extend to a part of the non-display area so as to be consistent with an end of a cathode of the light-emitting element.

Although the example embodiments of the present disclosure have been described in detail with reference to the accompanying drawings, the present disclosure is not limited thereto and can be embodied in many different forms without departing from the technical concept of the present disclosure. Therefore, the example embodiments of the present disclosure are provided for illustrative purposes only but not intended to limit the technical concept of the present disclosure. The scope of the technical concept of the present disclosure is not limited thereto. Therefore, it should be understood that the above-described example embodiments are illustrative in all aspects and do not limit the present disclosure. All the technical concepts in the equivalent scope of the present disclosure should be construed as falling within the scope of the present disclosure.

What is claimed is:

1. An electroluminescent display device comprising:
a substrate including a display area and a non-display area disposed outside the display area;
an insulation layer disposed on the substrate;
a light-emitting element disposed on the insulation layer;
a bonding layer disposed on the light-emitting element;
an encapsulation substrate disposed on the bonding layer; and
a side seal covering side surfaces of the bonding layer and the encapsulation substrate.

2. The electroluminescent display device according to claim 1, further comprising a flexible film disposed at one end of the non-display area,
wherein the side seal is disposed on the non-display area of three surfaces that surround a periphery of the display area, except for an end area to which the flexible film is attached.

3. The electroluminescent display device according to claim 2, further comprising an optical member disposed on a rear surface of the substrate; and
an additional side seal disposed at an upper outer side of the optical member.

4. The electroluminescent display device according to claim 3, wherein the additional side seal is disposed on the non-display area of the three surfaces that surround the periphery of the display area, except for the end area to which the flexible film is attached.

5. The electroluminescent display device according to claim 3, wherein the additional side seal covers side surfaces of the substrate and the insulation layer.

6. The electroluminescent display device according to claim 5, wherein the additional side seal extends to cover a part of the side seal.

7. The electroluminescent display device according to claim 3, further comprising an additional bonding layer disposed at an outer side of the side seal and a top surface of the encapsulation substrate, so as to guide a moisture penetration route from a direction toward a side surface of the electroluminescent to a direction toward an upper side of the encapsulation substrate along the additional bonding layer.

8. The electroluminescent display device according to claim 7, wherein the additional bonding layer covers side surfaces of the substrate and the insulation layer, the outer side of the side seal and the top surface of the encapsulation substrate.

9. The electroluminescent display device according to claim 7, further comprising a flexible film disposed at one end of the non-display area,
wherein the additional bonding layer is disposed on the non-display area of the three surfaces that surround the periphery of the display area, except for the end area to which the flexible film is attached.

10. The electroluminescent display device according to claim 7, wherein each of the boding layer and the additional bonding layer includes isobutyl rubber resin and a moisture absorbent.

11. The electroluminescent display device according to claim 7, wherein the additional side seal covers a part of a side surface of the additional bonding layer.

12. The electroluminescent display device according to claim 3, wherein the additional side seal includes acrylic resin.

13. The electroluminescent display device according to claim 3, wherein the additional side seal has a thickness of about 80 to 140 um.

14. The electroluminescent display device according to claim 7, wherein the additional bonding layer has a thickness of about 30 to 50 um.

15. The electroluminescent display device according to claim 7, further comprising an additional encapsulation substrate disposed at an outer side of the additional bonding layer.

16. The electroluminescent display device according to claim 15, wherein the additional encapsulation substrate has a thickness of about 10 to 30 um.

17. The electroluminescent display device according to claim 15, wherein the additional encapsulation substrate includes an aluminum foil.

18. The electroluminescent display device according to claim 15, wherein the additional side seal covers a part of a side surface of the additional encapsulation substrate.

19. The electroluminescent display device according to claim 7, wherein the additional bonding layer is disposed on a top surface of the insulation layer and covers the outer side of the side seal and the top surface of the encapsulation substrate.

20. The electroluminescent display device according to claim 15, wherein the additional encapsulation substrate is disposed on a top surface of the insulation layer and covers an outer side of the additional bonding layer.

21. The electroluminescent display device according to claim 15, wherein the additional side seal covers a part of a side surface of the additional encapsulation substrate.

22. The electroluminescent display device according to claim 1, wherein the side seal is disposed on a top surface of the insulation layer, the side surface of the bonding layer, and the side surface of the encapsulation substrate.

23. The electroluminescent display device according to claim 1, further comprising a connection electrode,
wherein the insulation layer includes a first planarization layer and a second planarization layer,
wherein the connection electrode is disposed on the first planarization layer and electrically connected to the light-emitting element, and
wherein the second planarization layer is disposed on the first planarization layer and the connection electrode, and the second planarization layer is formed so that a part of the connection electrode is exposed.

24. The electroluminescent display device according to claim 1, further comprising a capping layer between the light-emitting element and the bonding layer,
wherein the capping layer includes an organic compound having a refractive index of about 1.7 or more.

25. The electroluminescent display device according to claim 24, wherein the capping layer extends to a part of the non-display area so as to be consistent with an end of a cathode of the light-emitting element.
